(19) United States
(12) Patent Application Publication
(10) Pub. No.: US 2007/0000771 A1
(43) Pub. Date: Jan. 4, 2007

(54) Method for manufacturing vehicle mirrors

(76) Inventors: Werner Lang, Ergersheim (DE); Jochen Bauer, Ergersheim (DE); Willi Felbinger, Markt Nordheim (DE); Rudolf Mayer, Gebsattel (DE)

Correspondence Address: MCNAIR LAW FIRM, P.A., P.O. BOX 10827, GREENVILLE, SC, 29603-0827, US

(21) Appl. No.: 11/474,844

(22) Filed: Jun. 26, 2006

(30) Foreign Application Priority Data
Jul. 1, 2005 (DE) 102005030900.3

(51) Int. Cl. B29C 59/00; C23C 14/00

(52) U.S. Cl. 204/192.27; 264/129

(57) ABSTRACT

Molding a carrier base from plastic having a curved base surface formed into a fixed shape prior to receiving a mirror coating. Sputtering a first mirror coating layer selected of chromium onto the curved base surface, wherein the first layer has a light reflectivity in the range of approximately 60% to 65% of visible electromagnetic radiation. Sputtering a second mirror coating layer of aluminum onto the first layer so that the second layer has a light reflectivity of at least about 80% of visible electromagnetic radiation and a maximum thickness of approximately 20% of the thickness of the first layer. The first and second mirror coating layers are applied to the curved base surface to have a combined layer thickness in the range of approximately 5 mm to 1 μm. Applying an anti-scratch coating onto the second mirror coating layer to resist damage to the first and second mirror coating layers.

### BACKGROUND OF THE INVENTION

1) Field of the Invention

The present invention relates to vehicle mirrors, and more particularly, to a method for manufacturing a curved plastic vehicle mirror having improved reflective characteristics.

2) Description of Related Art

Vehicle mirrors are largely manufactured by a process wherein a thin layer of chromium, aluminum or silver, or another similar light reflective metal and, typically, a binder therefore is deposited from a vaporized state onto a body of metal or glass, which serves as a carrier base. Metal or glass bodies serving as carrier plates are disadvantageously heavy and contribute to high manufacturing costs for a finished mirror. Further, carrier plates made of metal or glass substances do not have the ability to elastically deform in, for example, a collision.

On account of these limitations, it has become known that it is advantageous to use mirrors with a carrier base made of lightweight plastic. It becomes immediately noticeable, however, that coating a plastic carrier base with chromium by known galvanic methods results in a friable chromium layer. Elastic deformation of the mirror often accompanies the installation process and can cause microfissures in the mirror coating, which leads to a cloudiness in the overall reflection of the mirror.

DE 697 08 926 T2 proposes that a flat, thermoplastic substrate, for instance PMMA (polymethylmethylacrylate), can be coating by sputtering a reflecting niobium layer onto the plastic substrate. It is important that the substrate receiving the coating have a flat receiving surface to maintain desired reflective characteristics. However, it is often the situation that subsequent to application of the reflective coating to the substrate, the mirror is heat treated for shaping into the desired mirror shape, which is normally a curved surface. Due to the sputtering process of applying the coating, when the substrate is shaped after the reflective coating is applied, the subsequent thermal shaping causes atomic diffusion and structural stratification in the coating. The resulting reflecting characteristics of the final curved mirror are disadvantageously altered to reduce the reflective quality of the mirror.

Giving consideration to the characteristics of the above DE 697 08 926 T2 reference, it is an object of this present invention to make available a manufacturing method that produces a curved mirror with a carrier base of plastic that exhibits better optical properties, notably among these being, advantages in quality of reflection, while avoiding the problems associated with heat treatment following coating of the substrate.

### SUMMARY OF THE INVENTION

The above objective is accomplished by providing in accordance with the present invention, a vehicle mirror manufactured in such a manner that first a carrier base of plastic is made in its final curved shaping, and subsequently, a thin mirror coating is applied on one side by means of sputtering.

Surprisingly, the result has been, that such carrier bases can be sputtered, which are not flat, but possess their final shape. Thereby, the previously employed subsequent shaping by thermal treatment is eliminated along with its inherent impairment regarding optical characteristics, in particular the quality of reflection.

The procedure in accord with the invention thus provides mirrors with improved optical properties, in contrast to mirrors constructed by a process following the state of the technology described above.

Contrary to the vehicle mirrors described in the opening passages, with metal or glass carrier bases, a mirror made in keeping with the invention is essentially lighter and more favorable in its function. It also has the ability of being elastically bent out of shape without breaking or being permanently deformed as in the case of a metal mirror or glass mirror. In addition the plastic dampens the vibrations that are common in the operation of a vehicle, so that the reflected image appears more steady. Advantageously, it has become evident that mirrors made by the invented procedure resisted degradation in reflected image quality resulting from frequent elastic deformation of the mirror reflective coating layer by avoiding thermal shaping subsequent to application of the reflective layer to the substrate.

Advantageously, the thin mirror coating includes a layer thickness of 5 mm to 1 μm. Such a coating thickness assures a sufficient adherence of the mirror coating to the carrier base, even in a case of an elastic deformation of the substrate, as well as, furnishing the desired optical characteristics, particularly among these, improved reflectivity.

Advantageously, the thin mirror coating encompasses a first layer of chromium or a chromium alloy, and preferably a second layer of aluminum or an aluminum alloy, which is placed on that side of the first layer which is remote from the carrier base.

Advantageously, the second layer, because of its reflectivity of at least 80% is considerably thinner than is the first layer with a reflectivity of some 60% to 65%. Advantageously, the thickness of the second layer is at the most, 50% of the first layer, although especially preferred at a maximum of 20% of the thickness of the first layer.

In another aspect of the invention, it is possible that “antiscratch” coatings, as these are known in liquid crystal displays or conventional mirrors, can be applied onto the thin mirror coating.

Further purposes, features, and advantages of the present invention can be found in the subordinate claims and the following explanatory embodiment examples.

### BRIEF DESCRIPTION OF THE DRAWINGS

The construction designed to carry out the invention will hereinafter be described, together with other features thereof. The invention will be more readily understood from a reading of the following specification and by reference to the accompanying drawing forming a part thereof, wherein an example of the invention is shown and wherein:

FIG. 1 shows a vehicle mirror in a cross-sectional version, which has been made in accordance with the procedure of the present invention, and;

FIG. 2 shows a flow chart of various steps in the method of producing the mirror according to the present invention.

### DETAILED DESCRIPTION OF A PREFERRED EMBODIMENT

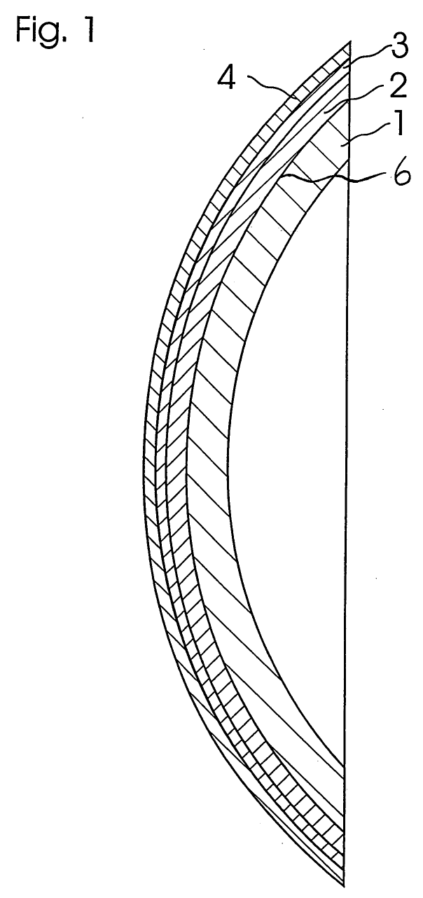

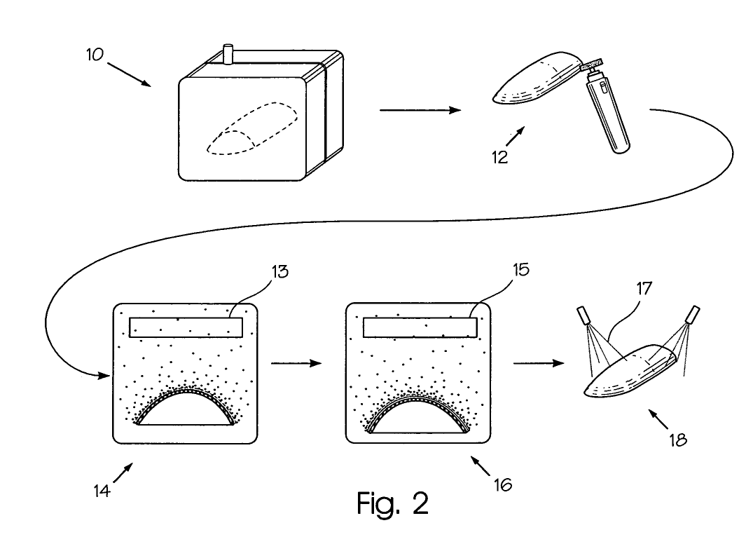

With reference to the drawing of FIGS. 1 and 2, the invention will now be described in more detail.

In accordance with one embodiment of the present invention, as a first step, a carrier base 1 is fabricated from plastic having a curved base surface 6 for receiving a mirror coating. This can be done by molding, shown at step 10, possibly by spraying, injecting, or pouring of a thermoplastic polymer, or the curing of a foamed plastic. Subsequently, carrier base 1 may still be reworked to a finished form by grinding, trimming, or the like, shown at step 12, prior to application of the mirror coating to curved base surface 6.

Once carrier base 1 is constructed and arranged in its final form, deposit of the mirror coating onto the carrier base can be accomplished by the sputtering application method. In order to deposit a thin first layer 2 of chromium, shown at step 14, a voltage is applied in a known way in a container filled with an inert noble gas so that the chromium atoms impelled out of a chromium target 13 by the noble gas ions are accelerated toward carrier base 1 and precipitate thereon to form first layer 2 by condensation. Appropriate sputtering equipment can be found, for example, in Inline Sputter Equipment A1250V with vertical transport and vertical magnetrons. U.S. Pat. No. 4,166,018 describes likewise a preferred sputtering unit, and is incorporated herein by reference in its entirety so that this disclosure can be applied to this case.

Following application of first layer 2, the same procedure is carried out with an aluminum target 15, in order to sputter a second layer 3 of aluminum onto first layer 2 of chromium, shown at step 16. By shortening the application time, it is possible to provide a thinner layer thickness for second layer 3. In a preferred embodiment, second layer 3, can be applied thinner than first layer 2 because of a higher reflectivity. The aluminum coating reflects approximately 80% of visible electromagnetic radiation as opposed to a reflectivity of approximately 60% to 65% by the chromium of first layer 2. Advantageously, the thickness of second layer 3 is at the most 50% of first layer 2. In a preferred embodiment, second layer 3 has a maximum thickness of 20% of first layer 2.

Preferably, the combined mirror coating includes a layer thickness of 5 mm to 1 μm. Such a coating thickness assures a sufficient adherence of the mirror coating to the carrier base, even in a case of an elastic deformation of the carrier base, as well as, furnishing the desired optical characteristics, particularly among these, improved reflectivity.

Advantageously, following application of second layer 3, it is possible, for example, to apply by spraying a transparent plastic or a resin coating 4 to further add an anti-scratch coating onto the mirror, shown at step 18.

The mirror is then in a finished state and needs no further after-work, especially heat treatment reshaping, that would impair the structure and the holding power of the layers which have already been sputtered on.

While a preferred embodiment of the invention has been described using specific terms, such description is for illustrative purposes only, and it is to be understood that changes and variations may be made without departing from the spirit or scope of the following claims.

What is claimed is:

1. A method for manufacturing a vehicle mirror having a curved mirror surface, particularly for use with commercial vehicles, comprising the steps of:
providing a carrier base having a curved base surface molded into a fixed shape during the original molding of the carrier base and prior to receiving a mirror coating; and,
sputtering a mirror coating onto said curved base surface following molding of said curved base surface to provide a vehicle mirror with a reflective surface free of atomic diffusion and structural stratification as occurs when said mirror coating is applied to said carrier base prior to forming said curved base surface.

2. The method of claim 1 including the step of molding said carrier base from a thermoplastic polymer.

3. The method of claim 2 including the step of sputtering a mirror coating having a layer thickness in the range of approximately 5 mm to 1 μm onto said curved base surface of said carrier base.

4. The method of claim 3 wherein said mirror coating is constructed of materials selected from the group consisting of chromium, chromium alloy, aluminum, aluminum alloy, and combinations thereof.

5. The method of claim 4 including the step of forming said mirror coating by sputtering a first layer selected from one of a chromium and a chromium alloy onto said curved base surface of said carrier base.

6. The method of claim 5 including the step of forming said first layer with a light reflectivity in the range of approximately 60% to 65% of visible electromagnetic radiation.

7. The method of claim 5 including the step of sputtering a second layer selected from one of a aluminum and a aluminum alloy onto said first layer.

8. The method of claim 7 including the step of forming said second layer with a light reflectivity of at least about 80% of visible electromagnetic radiation.

9. The method of claim 7 including the step of forming said second layer thinner than said first layer.

10. The method of claim 7 including the step of forming said second layer with a thickness approximately 50% or less than the thickness of said first layer.

11. The method of claim 7 including the step of applying an anti-scratch coating onto said second layer.

12. A method for manufacturing a curved vehicle mirror comprising the steps of:
molding a carrier base from a thermoplastic polymer having a curved base surface being formed into a fixed shape prior to receiving a mirror coating;
sputtering a first mirror coating layer selected from one of a chromium and a chromium alloy onto said curved base surface of said carrier base, wherein said first mirror coating layer has a light reflectivity in the range of approximately 60% to 65% of visible electromagnetic radiation;
sputtering a second mirror coating layer selected from one of a aluminum and a aluminum alloy onto said first layer, wherein said second layer has a light reflectivity of at least about 80% of visible electromagnetic radiation; and,
wherein said first and second mirror coatings are applied to said curved base surface to have a combined layer thickness in the range of approximately 5 mm to 1 μm.

13. The method of claim 12 including the step of forming said second layer thinner than said first layer.

14. The method of claim 13 including the step of forming said second layer with a maximum thickness of approximately 20% of the thickness of said first layer.

15. The method of claim 13 including the step of applying an anti-scratch coating onto said second layer.

16. A method for manufacturing a curved vehicle mirror comprising the steps of:
molding a carrier base from a thermoplastic polymer having a curved base surface being formed into a fixed shape prior to receiving a mirror coating;
sputtering a first mirror coating layer selected from one of a chromium and a chromium alloy onto said curved base surface of said carrier base, wherein said first mirror coating layer has a light reflectivity in the range of approximately 60% to 65% of visible electromagnetic radiation;
sputtering a second mirror coating layer selected from one of a aluminum and a aluminum alloy onto said first layer so that said second mirror coating layer has a light reflectivity of at least about 80% of visible electromagnetic radiation and a maximum thickness of approximately 20% of the thickness of said first layer, wherein said first and second mirror coating layers are applied to said curved base surface to have a combined layer thickness in the range of approximately 5 mm to 1 μm; and,
applying an anti-scratch coating onto said second mirror coating layer to resist damage to said first and second mirror coating layers.
